(19) United States
(12) Patent Application Publication
(10) Pub. No.: US 2025/0192498 A1
(43) Pub. Date: Jun. 12, 2025

(54) JUMPER BAR FOR USE WITH A BUILDING CONTROLLER

(71) Applicant: HONEYWELL INTERNATIONAL INC., Charlotte, NC (US)

(72) Inventors: Michael ZHENG, Beijing (CN); Ke ZHANG, Beijing (CN); Haitao LI, Beijing (CN); Cary LEEN, Hammond, WI (US)

(21) Appl. No.: 18/843,126

(22) PCT Filed: Mar. 4, 2022
(86) PCT No.: PCT/CN2022/079256

§ 371 Date: Aug. 30, 2024

(51) Int. Cl. H01R 31/08; H05K 7/14

(52) U.S. Cl. CPC H01R 31/08; H05K 7/1452

(57) ABSTRACT

An electronic module having one or more jumper sockets defining three or more terminals, and a housing that includes one or more apertures for accessing the terminals from external to the housing. The jumper bar includes a jumper body and three or more spaced jumper terminals that are secured to and extend away the jumper body. In use, a first part of the jumper bar remains outside of the housing and a second part of the jumper bar, including at least part of each of the three or more spaced jumper terminals, extends through one or more of the apertures in the housing. Each of the jumper terminals of the jumper bar electrically engage a corresponding one of the three or more terminals. The first part of the jumper bar includes a graspable handle with a flange for pulling the jumper bar from the electronic module by hand.

### TECHNICAL FIELD

The present disclosure pertains generally to jumper bars used with a building controller.

### BACKGROUND

A variety of electronic modules such as controllers and IO modules are used in controlling a variety of different systems such as building systems, industrial control systems, process control systems and the like. Depending on the particular system involved, the electronic module must be connected in the field to one or more other devices such as one or more sensors, one or more actuators, one or more controllers and the like. To support such wired connections, the electronic module may include one or more terminal blocks that allow an installer to secure connecting wires to the electronic module. However, in some installations, it can be difficult and/or time consuming to make the necessary wiring connections because of the construction, design and placement of the terminal blocks and/or other components of the electronic module. A need remains for an improved design that supports making the necessary wiring connections to such electronic modules.

### SUMMARY

This disclosure relates generally to jumper bars. An example may be found in an apparatus that includes an electronic module and a jumper bar. The electronic module includes one or more circuit boards including one or more jumper sockets, and a housing that is configured to house the one or more circuit boards. The one or more jumper sockets defining three or more terminals. The housing including one or more apertures for accessing the three or more terminals defined by the one or more jumper sockets from external to the housing. The jumper bar includes a jumper body and three or more spaced jumper terminals that are secured to and extend away the jumper body. The three or more jumper terminals electrically shorted together. In use, the jumper bar is positioned such that a first part of the jumper bar remains outside of the housing of the electronic module and a second part of the jumper bar, which includes at least part of each of the three or more spaced jumper terminals of the jumper bar, extends into and through one or more of the apertures in the housing of the electronic module. Each of the three or more spaced jumper terminals of the jumper bar electrically engage a corresponding one of the three or more terminals defined by the one or more jumper sockets of the one or more circuit boards of the electronic module. The first part of the jumper bar that remains outside of the housing of the electronic module includes a graspable handle with a flange for pulling the jumper bar from the electronic module by hand.

Another example is found in a jumper bar that includes three or more spaced jumper terminals that are electrically shorted together, and a jumper body that includes an elongated base. Each of the three or more spaced jumper terminals are secured to the elongated base at spaced locations along a length direction of the elongated base and extend away from the elongated base in a first direction. The spaced locations are offset toward one side of the elongated base in a width direction.

Another example is found in a jumper bar that includes three or more spaced jumper terminals that are electrically shorted together. The jumper bar includes a jumper bar having an elongated base, wherein each of the three or more spaced jumper terminals are secured to the elongated base at spaced locations along a length direction of the elongated base and extend away from the elongated base in a first direction. The jumper bar further includes a handle support that extends from the elongated base away from the first direction, and a graspable handle that is supported by the handle support. The graspable handle includes a flange that extends out from the handle support in a lateral direction.

The preceding summary is provided to facilitate an understanding of some of the features of the present disclosure and is not intended to be a full description. A full appreciation of the disclosure can be gained by taking the entire specification, claims, drawings, and abstract as a whole.

### BRIEF DESCRIPTION OF THE DRAWINGS

The disclosure may be more completely understood in consideration of the following description of various illustrative embodiments of the disclosure in connection with the accompanying drawings, in which:

FIG. 1 is a perspective view of an illustrative electronic module including auxiliary terminal blocks, push-in terminal blocks and a jumper bar;

FIG. 2A is a perspective view of the illustrative electronic module without the auxiliary terminal blocks, push-in terminal blocks and jumper bar shown in FIG. 1;

FIG. 2B is a perspective view of an illustrative electronic module including covers;

FIG. 3 is a perspective view of an illustrative auxiliary terminal block as included in FIG. 1;

FIG. 4 is an upward facing perspective view of the illustrative auxiliary terminal block of FIG. 3;

FIG. 5 is an opposing perspective view of the illustrative auxiliary terminal block of FIG. 3;

FIG. 6 is a perspective view of the illustrative auxiliary terminal block of FIG. 2, with an outer housing removed;

FIG. 7A is a perspective view of an illustrative circuit board found within the illustrative electronic module of FIG. 1, showing illustrative sockets for accepting push-in terminal blocks and a jumper bar;

FIG. 7B is a perspective view of an illustrative circuit board found within the illustrative electronic module of FIG. 2B, showing illustrative sockets for accepting push-in terminal blocks and a jumper bar;

FIG. 8 is a front perspective view of an illustrative push-in terminal block as included in FIG. 1;

FIG. 9 is a top view of the illustrative push-in terminal block of FIG. 8;

FIG. 10A is a bottom view of the illustrative push-in terminal block of FIG. 8;

FIG. 10B is a bottom perspective view of the illustrative push-in terminal block of FIG. 8;

FIG. 10C is a side perspective view of an illustrative push-in terminal block with an alternate external cover;

FIG. 11 is a front view of the illustrative push-in terminal of FIG. 8, with the cover removed to reveal the electrical terminals disposed within the illustrative push-in terminal;

FIG. 12 is an exploded perspective view of one of the electrical terminals of FIG. 11;

FIG. 13 is an enlarged view of a portion of FIG. 2 for receiving jumper terminals of an illustrative jumper bar as included in FIG. 1;

FIG. 14 is a perspective view of the illustrative jumper bar as included in FIG. 1;

FIG. 14A is a front view of the illustrative jumper of FIG. 14 shown in position relative to the circuit board shown in FIG. 7A;

FIG. 14B is a side view of the illustrative jumper bar of FIG. 14 shown in position relative to the circuit board shown in FIG. 7A;

FIG. 15 is a perspective view of the illustrative jumper bar of FIG. 14 engaged in a pair of sockets as shown in FIG. 7;

FIG. 16 is a perspective view of the illustrative jumper bar of FIG. 14 engaged in a pair of sockets as shown in FIG. 7, with the covers removed from the pair of sockets to reveal the internal structure; and

FIG. 17 is a schematic view showing a jumper bar in use.

While the disclosure is amenable to various modifications and alternative forms, specifics thereof have been shown by way of example in the drawings and will be described in detail. It should be understood, however, that the intention is not to limit aspects of the disclosure to the particular illustrative embodiments described. On the contrary, the intention is to cover all modifications, equivalents, and alternatives falling within the spirit and scope of the disclosure.

### DESCRIPTION

The following description should be read with reference to the drawings wherein like reference numerals indicate like elements. The drawings, which are not necessarily to scale, are not intended to limit the scope of the disclosure. In some of the figures, elements not believed necessary to an understanding of relationships among illustrated components may have been omitted for clarity.

All numbers are herein assumed to be modified by the term “about”, unless the content clearly dictates otherwise. The recitation of numerical ranges by endpoints includes all numbers subsumed within that range (e.g., 1 to 5 includes 1, 1.5, 2, 2.75, 3, 3.80, 4, and 5).

As used in this specification and the appended claims, the singular forms “a”, “an”, and “the” include the plural referents unless the content clearly dictates otherwise. As used in this specification and the appended claims, the term “or” is generally employed in its sense including “and/or” unless the content clearly dictates otherwise.

It is noted that references in the specification to “an embodiment”, “some embodiments”, “other embodiments”, etc., indicate that the embodiment described may include a particular feature, structure, or characteristic, but every embodiment may not necessarily include the particular feature, structure, or characteristic. Moreover, such phrases are not necessarily referring to the same embodiment. Further, when a particular feature, structure, or characteristic is described in connection with an embodiment, it is contemplated that the feature, structure, or characteristic may be applied to other embodiments whether or not explicitly described unless clearly stated to the contrary.

Electronic modules such as but not limited to controllers and IO modules may be used in a variety of control systems such as building systems, industrial control systems, process control systems and the like. One particular example is a building control system, where one or more controllers may be provided for controlling various building control systems such as a Heating, Ventilating and Air Conditioning (HVAC) system, a security system, a fire suppression system and/or the like. Continuing with this example, an HVAC controller may control operation of the entire HVAC system of the building or only part of an HVAC system. In some cases, an IO module may be used in conjunction with an HVAC controller in order to provide the HVAC controller with additional inputs and/or additional outputs for controlling various HVAC devices. These are just examples.

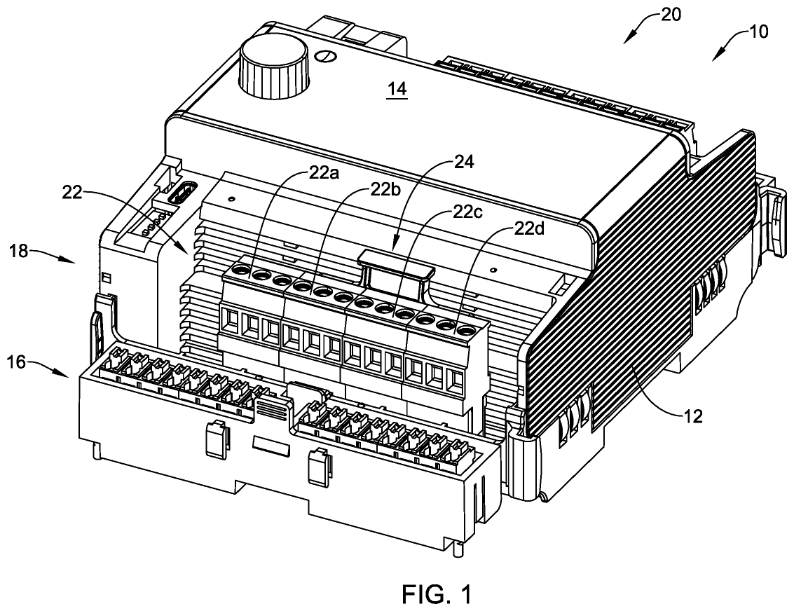

FIG. 1 is a perspective view of an illustrative electronic module 10. The illustrative electronic module 10 may represent a controller or an IO module, for example. The electronic module 10 includes a housing 12 having a front panel 14. While the back of the housing 12 is not shown, it will be appreciated that the housing 12 may be configured to allow attachment of the electronic module 10 directly to a vertical surface such as a wall or an interior surface of an electrical panel. The housing 12 may be configured to allow attachment of the electronic module 10 to a DIN rail.

In some cases, particularly if the electronic module 10 represents a controller, the front panel 14 may include buttons, switches or a display that may be used to enter information into the controller, control various settings and/or modes of the controller, and/or display various information. If the electronic module 10 represents an IO module, the front panel 14 may not include many or even any buttons, switches or displays. In some cases, the IO module may be controlled by, and in some cases act as a slave to a master controller.

As shown, the illustrative electronic module 10 includes several optional components that may be added to the electronic module 10 in the field, sometimes without requiring the use of any tools to add the optional components. For example, the electronic module 10 as shown includes an auxiliary terminal block 16 that is secured to a first side 18 of the electronic module 10 that may be considered as being a lower side of the electronic module 10 once the electronic module 10 has been mounted for use. The auxiliary terminal block 16 may be used to permit additional wiring connections. While a single auxiliary terminal block 16 is visible, it will be appreciated that there may be another auxiliary terminal block secured relative to a second side 20 of the electronic module 10 that may be considered as being an upper side of the electronic module 10 once the electronic module 10 has been mounted for use.

In some cases, two or more auxiliary terminal blocks 16 may be joined together on the first side 18 of the electronic module 10 and/or the second side 20 of the electronic module 10. As will be discussed, the illustrative auxiliary terminal block 16 includes a first set of attachment features that are configured to releasably engage corresponding structure formed on an exterior of the housing 12 as well as to emulate those structures on an opposing side of the auxiliary terminal block 16 that can releasable engage a first set of attachment features on a second auxiliary terminal block 16.

The electronic module 10 includes, as shown, several push-in terminal blocks 22, individually labeled as 22a, 22b, 22c and 22d. As will be discussed, each of the push-in terminal blocks 22 is configured to allow electrical conductors such as wires to be mechanically and electrically secured within the push-in terminal block 22, as well as being configured to allow a test probe to be used while the electrical conductors are secured within the push-in terminal block 22. Each push-in terminal block 22 is configured to allow a user to easily remove the electrical conductors from the push-in terminal block 22 when desired to do so. While a total of four push-in terminal blocks 22 are shown on the first side 18 of the electronic module 10, it will be appreciated that the electronic module 10 may only include one push-in terminal block 22, two push-in terminal blocks 22 or three push-in terminal blocks 22, depending on the wiring requirements of the electronic module 10. In some cases, more than four push-in terminal blocks 22 may be included.

The illustrative electronic module 10 includes, as shown, a jumper bar 24 disposed on the first side 18 of the electronic module 10. The jumper bar 24 may be seen as extending upward relative to the push-in terminal blocks 22 such that the jumper bar 24 may be accessible to a user to be inserted and/or removed regardless of whether the push-in terminal blocks 2 are present or absent. As will be discussed, the jumper bar 24 may optionally be used to electrically short together two or more electrical contacts within the electronic module 10. For example, a power source may be coupled to one electrical contact within the electronic module 10. By shorting that electrical contact to one, two or more other electrical contacts within the electronic module 10, wires may be coupled to each of the shorted together electrical contacts to provide the power source to the other connected components, rather than having to manually couple several wires together, such as by joining several wires together with a wire nut. Using the jumper bar 24 may be faster, more efficient, more reliable, and cleaner than other techniques. While not shown, there may also be a jumper bar 24 disposed on the second side 20 of the electronic module 10 when desired.

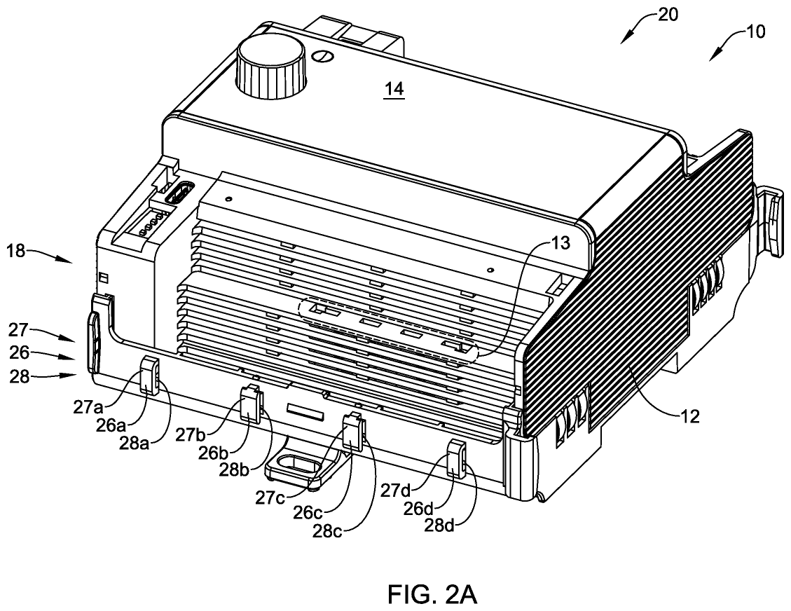

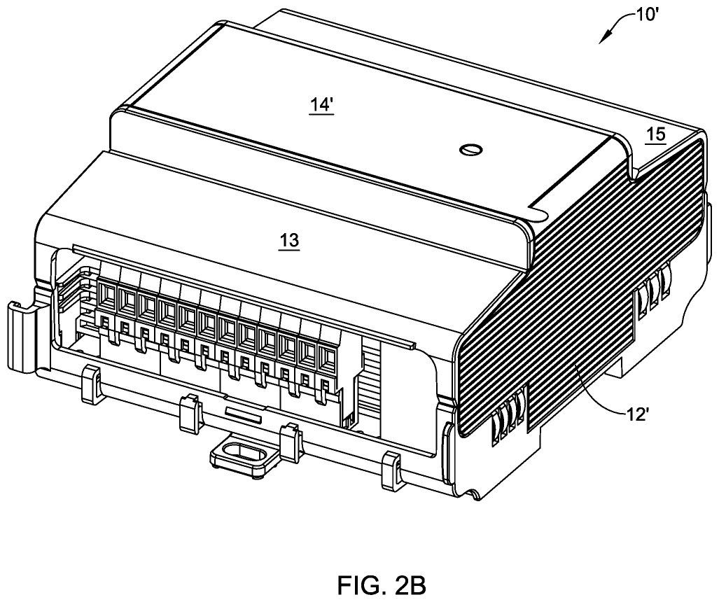

FIG. 2A is a perspective view of the electronic module 10 with the auxiliary terminal block 16, the push-in terminal blocks 22 and the jumper bar 24 removed, or otherwise not coupled with the electronic module 10. It can be seen that the housing 12 on the front side 18 of the electronic module 10 includes several attachment features 26, individually labeled as 26a, 26b, 26c and 26d. While a total of four attachment features 26 are shown, it will be appreciated that the electronic module 10 may include only one, two, or three attachment features 26, or may include five or more attachment features 26. In the example shown, each of the attachment features 26 include an enlarged head 27, individually labeled as 27a, 27b, 27c and 27d.

In some cases, the attachment features 26 include a zip tie aperture 28, individually labeled as 28a, 28b, 28c and 28d that extends through the attachment feature 26. In some cases, particularly if the auxiliary terminal block 16 is not being used, the zip tie apertures 28 may be used to accommodate a zip-tie therethrough that can be used to bundle, organize or otherwise help to secure some of the wires that may be coupled to the electronic module 10. In some cases, the attachment features 26 can be used to provide a strain relief function, where each of the zip tie apertures 28 can accommodate a zip tie that an installer can use to secure wires that are ultimately connected to the push-in-terminal block 22 so as to relieve strain on the connection between the wires and the push-in terminal block 22.

FIG. 2B is a perspective view of an electronic module 10′ that may represent a controller or an IO module, for example. The electronic module 10′ may be considered as being very similar to the electronic module 10, but with minor differences. Any features ascribed to the electronic module 10 may be included within the electronic module 10′, and any features ascribed to the electronic module 10′ may be included within the electronic module 10.

The electronic module 10′ includes a housing 12′ having a front panel 14′. While the back of the housing 12′ is not shown, it will be appreciated that the housing 12′ may be configured to allow attachment of the electronic module 10′ directly to a vertical surface such as a wall or an interior surface of an electrical panel. The housing 12′ may be configured to allow attachment of the electronic module 10′ to a DIN rail.

In some cases, particularly if the electronic module 10′ represents a controller, the front panel 14′ may include buttons, switches or a display that may be used to enter information into the controller, control various settings and/or modes of the controller, and/or display various information. If the electronic module 10′ represents an IO module, the front panel 14′ may not include many or even any buttons, switches or displays. In some cases, the IO module may be controlled by, and in some cases act as a slave to a master controller.

The electronic module 10′ may include a first cover 13 and a second cover 15. In some instances, the first cover 13 and the second cover 15 may be attached to the housing 12′ via an interference fit. The first cover 13 and the second cover 15 may snap into place, for example. The first cover 13 and the second cover 15 may be sufficiently flexible to be able to flex slightly in order to be snapped into position. The first cover 13 and the second cover 15 may be used together, or in some cases only the first cover 13 is used and the second cover 15 is not. In some instances, the second cover 15 may be used while the first cover 13 is not. The first cover 13 and the second cover 15 may be made of a polymeric material similar or even identical to the polymeric material used to form the housing 12′. In some cases, the first cover 13 and/or the second cover 15 may extend along a plane that is non-parallel with the housing 12′ of the electronic module 10′.

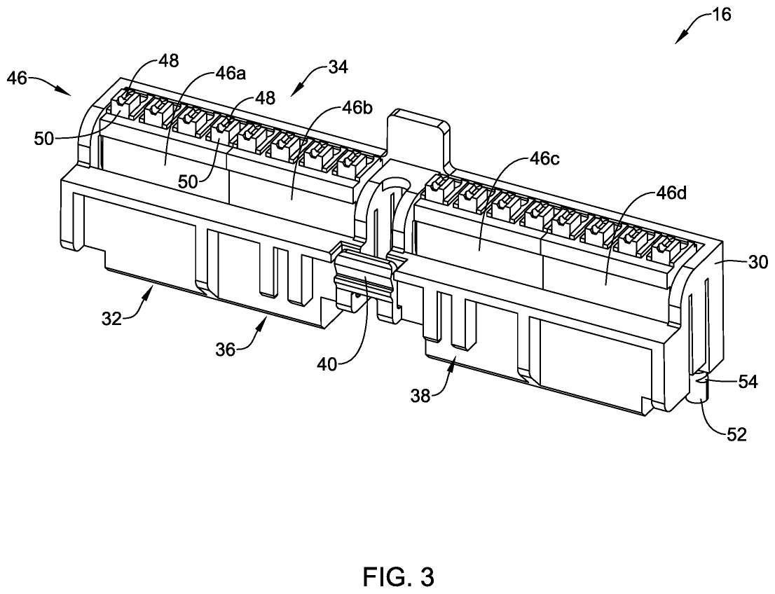

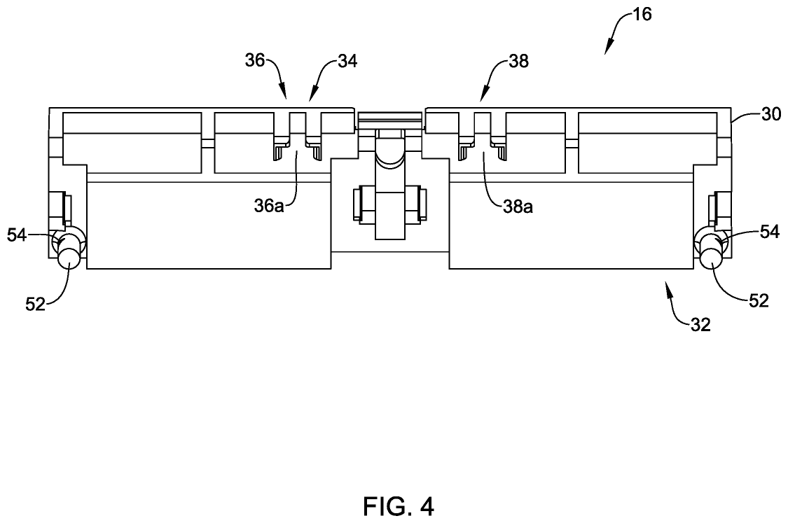

FIG. 3 is a perspective view of the auxiliary terminal block 16 while FIG. 4 is an upward facing perspective view of the auxiliary terminal block 16. The illustrative auxiliary terminal block 16 includes a housing 30 having a first side 32 and a second side 34. The first side 32 corresponds to a side of the auxiliary terminal block 16 that may, if desired, be secured to the electronic module 10 while the second side 34 corresponds to an opposing side of the auxiliary terminal block 16 that is exposed when the auxiliary terminal block 16 is secured to the electronic module 10. As will be discussed, the second side 34 of the housing 30 includes attachment features that facilitate attaching a second auxiliary terminal block 16 to a first auxiliary terminal block 16, or attaching a third auxiliary terminal block 16 to a second auxiliary terminal block 16, for example.

The first side 32 of the housing 30 includes several attachment features 36 and 38 that are configured to releasably engage with the attachment features 26 disposed on the electronic module 10 (as shown in FIG. 2). The attachment features 36 and 38 include a channel 36a and a channel 38a, respectively. Each of the channels 36a and 36b are configured to accommodate a corresponding enlarged head of the attachment features extending from the housing 30 of the electronic module 10.

It will be appreciated that the auxiliary terminal block 16 can be secured to the electronic module 10 by aligning the attachment features 36 and 38 with the corresponding attachment features 26b and 26c of the electronic module 10, and sliding the auxiliary terminal block 16 such that the attachment features 26b and 26c of the electronic module 10 slid into the corresponding channels 36a and 38a, respectively. The auxiliary terminal block 16 includes a latch 40 that can releasable engage the housing 12 of the electronic module 10 in order to secure the auxiliary terminal block 16 in place relative to the housing 12 of the electronic module 10.

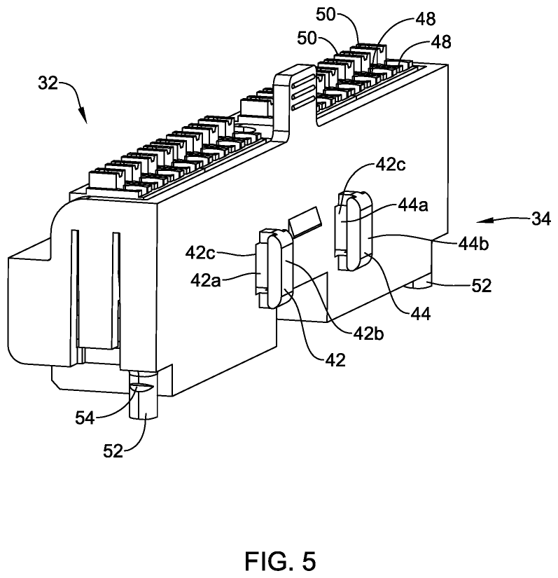

FIG. 5 is a perspective view of the second side 34 of the auxiliary terminal block 16. It can be seen that the second side 34 of the auxiliary terminal block 16, which will face outwardly when the auxiliary terminal block 16 is secured to the electronic module 10, includes several attachment features 42 and 44. While two attachment features 42 and 44 are shown, it will be appreciated that the second side 34 of the auxiliary terminal block 16 may include a single such attachment feature, or may include three or more attachment features, as long as the number and relative position of the attachment features on the second side 34 of the auxiliary terminal block 16 are complementary to the number and relative position of the attachment features on the first side 32 of the auxiliary terminal block 16, thereby allowing a second auxiliary terminal block 16 being secured to a first auxiliary terminal block 16, or allowing a third auxiliary terminal block 16 being secured to a second auxiliary terminal block 16.

The attachment features 42 and 44 may be similar or identical to the attachment features 26b and 26c of the electronic module 10. The attachment features 42 and 44 include a zip tie aperture 42a and 44a, respectively. The attachment features 42 and 44 also include enlarged heads 42b and 44b that are supported by a neck 42c and a neck 44c, respectively. In some cases, particularly if there isn't an additional auxiliary terminal block 16 secured to the illustrated auxiliary terminal block 16, the zip tie apertures 42a and 44a may be used to accommodate a zip-tie therethrough that can be used to bundle, organize or otherwise help to secure some of the wires that may be coupled to the electronic module 10, sometimes performing a strain relief function.

Returning briefly to FIG. 3, the auxiliary terminal block 16 includes one or more connection blocks 46, individually labeled as 46a, 46b, 46c and 46d. Each of the connection blocks 46 may be considered as including a number of wire receiving apertures 48 that are configured to accommodate a wire extending into one or more of the wire receiving apertures 48. Each connection block 46 also includes a number of release buttons 50, with one release button 50 corresponding to each of the wire receiving aperture 48. In some cases, the release button 50 is depressed simultaneously with inserting a wire into the wire receiving aperture 48 corresponding to the particular release button 50. In some instances, a wire may be inserted into the wire receiving aperture 48 without depressing the corresponding release button 50, but the corresponding release button 50 may be used if there is a desire to remove the wire disposed within the corresponding wire receiving aperture 48.

In some instances, as shown, the auxiliary terminal block 16 includes several legs 52 that extend away from the housing 30. The legs 52 have a length that is sufficient to allow the legs 52 to engage a mounting wall when the electronic module 10 is spaced away from the mounting wall as a result of being secured to a DIN rail. In the example shown, the legs 52 each include a score 54 that facilitates each leg 52 being snapped off at the score 54, in order to provide each leg 52 with a shorter length that allows the housing 30 itself to engage a mounting wall when the electronic module 10 is secured directly to the mounting wall. In some cases, the legs may be snapped off at the score 54 by hand without the need for any tool.

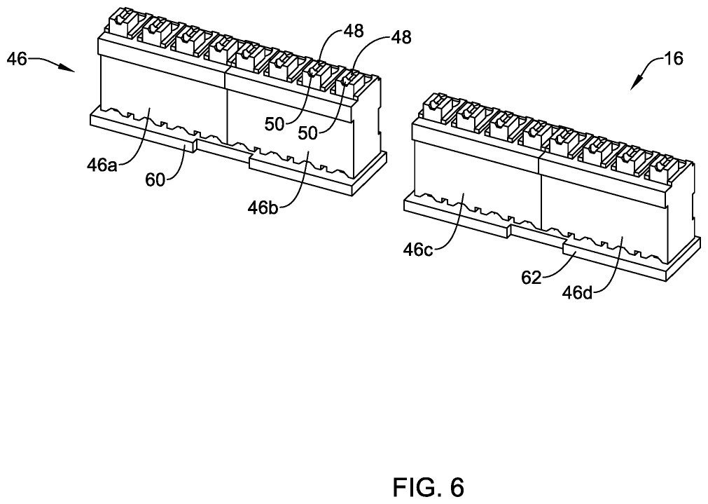

FIG. 6 shows the auxiliary terminal block 16 with the housing 30 removed to show internal structure. The auxiliary terminal block 16 includes a first circuit board 60 and a second circuit board 62, with the connection block 46a and the connection block 46b mechanically and electrically coupled to the first circuit board 60 and with the connection block 46c and the connection block 46d mechanically and electrically coupled to the second circuit board 62. In some instances, the first circuit board 60 and the second circuit board 62 may not be distinct circuit boards, but may be a single circuit board that is mechanically and electrically coupled to the connection block 46a, the connection block 46b, the connection block 46c and the connection block 46d.

In some instances, the first circuit board 60 includes electrically conductive traces that short one or more of the electrical terminals within the connection block 46a and/or the connection block 46b. In some cases, the first circuit board 60 may include one or more resisters that are used to electrically short together two or more of the electrical terminals within the connection block 46a and/or the connection block 46b. In some cases, all of the electrical terminals within the connection block 46a and all of the electrical terminals within the connection block 46b are electrically shorted together via structure on the first circuit board 60.

In some instances, the second circuit board 62 includes electrically conductive traces that short one or more of the electrical terminals within the connection block 46c and/or the connection block 46d. In some cases, the second circuit board 62 may include one or more resisters that are used to electrically short together two or more of the electrical terminals within the connection block 46c and/or the connection block 46d. In some cases, all of the electrical terminals within the connection block 46c and all of the electrical terminals within the connection block 46d are electrically shorted together via structure on the second circuit board 62.

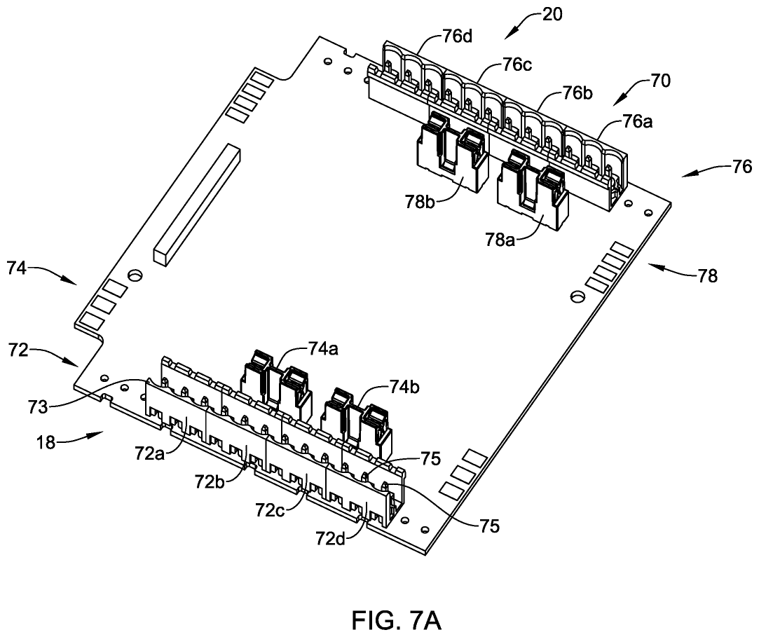

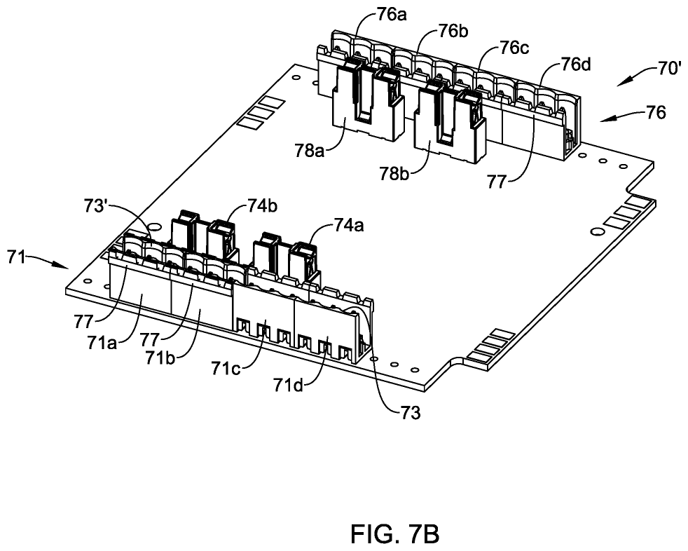

FIG. 7A is a perspective view of an illustrative circuit board 70 found within the illustrative electronic module 10. The circuit board 70 includes sockets for accepting the push-in terminal blocks 22 as well as sockets for accepting the jumper bar 24. In particular, the illustrative circuit board 70 includes a number of terminal block sockets 72, individually labeled as 72a, 72b, 72c and 72d, for accepting corresponding electrical contacts extending from each of a number of push-in terminal blocks 22. While a total of four terminal block sockets 72 are shown, it will be appreciated that this is merely illustrative, as the circuit board 70 may include one, two, three or more terminal block sockets 72 that are each the same size as shown, or can be different sizes. In some cases, a single terminal block socket 72 may accommodate one, two, three, four or even more push-in terminal blocks 22.

As can be seen, each of the terminal block sockets 72 includes one side that has an undulating surface 73. As will be discussed, the undulating surface 73 is complementary to a similar undulating surface on part of the push-in terminal block 22 in order to ensure that each push-in terminal block 22 is inserted in the appropriate orientation. Each of the terminal block sockets 72 include a number of electrical pins 75 (for clarity, only two are labeled) that are electrically coupled to circuitry (not shown) on the circuit board 70 and that are configured to electrically couple with corresponding electrical contacts within each of the push-in terminal blocks 22.

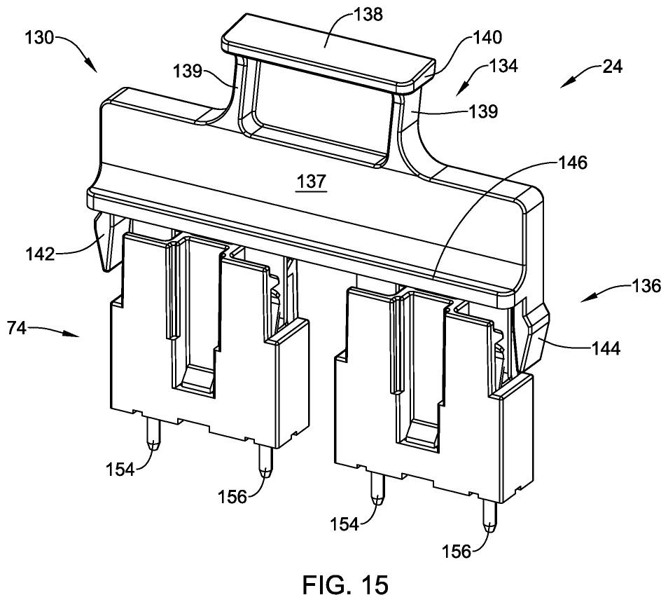

The circuit board 70 includes several jumper sockets 74, individually labeled as 74a and 74b, for accepting electrical contacts within the jumper bar 24. In some cases, the circuit board 70 may only include a single jumper socket 74 that spans the distance currently consumed by both the jumper socket 74a and the jumper socket 74b. Further details regarding the jumper sockets 74 will be discussed with respect to FIG. 15.

The illustrative circuit board 70 includes a number of terminal block sockets 76, individually labeled as 76a, 76b, 76c and 76d, for accepting corresponding electrical contacts extending from each of a number of push-in terminal blocks 22. While a total of four terminal block sockets 76 are shown, it will be appreciated that this is merely illustrative, as the circuit board 70 may include one, two, three or more terminal block sockets 76 that are each the same size as shown, or can be different sizes. In some cases, a single terminal block socket 76 may accommodate one, two, three, four or more push-in terminal blocks 22. Each of the terminal block sockets 76 include a number of electrical pins that are electrically coupled to circuitry (not shown) on the circuit board 70 and that are configured to electrically couple with corresponding electrical contacts within each of the push-in terminal blocks 22.

The illustrative circuit board 70 includes several jumper sockets 78, individually labeled as 78a and 78b, for accepting electrical contacts within the jumper bar 24. In some cases, the circuit board 70 may only include a single jumper socket 78 that spans the distance currently consumed by both the jumper socket 78a and the jumper socket 78b.

FIG. 7B is a perspective view of an illustrative circuit board 70′ that is similar to the circuit board 70 described with respect to FIG. 7A. It will be appreciated that the circuit board 70′ has been rotated 180 degrees from the orientation of the circuit board 70. The illustrative circuit board 70′ includes a number of terminal block sockets 71, individually labeled as 71a, 71b, 71c and 71d, for accepting corresponding electrical contacts extending from each of a number of push-in terminal blocks 22. While a total of four terminal block sockets 71 are shown, it will be appreciated that this is merely illustrative, as the circuit board 70′ may include one, two, three or more terminal block sockets 71 that are each the same size as shown, or can be different sizes. In some cases, a single terminal block socket 71 may accommodate one, two, three, four or even more push-in terminal blocks 22.

As can be seen, the terminal block sockets 71c and 71d have an undulating surface 13 that, as will be discussed, is complementary to a similar undulating surface on part of the push-in terminal block 22 in order to ensure that each push-in terminal block 22 is inserted in the appropriate orientation, and only into a socket 71 that is intended for use with a particular push-in terminal block 22. It will be appreciated that some push-in terminal blocks 22 may be designed for use with a variety of voltages, up to and including line voltage, while others are intended only for low voltage use.

The terminal block sockets 71a and 71b have an undulating surface 73′ that is similar to the undulating surface 73, but is located on an opposite side of the terminal block sockets 71a and 71b. If someone attempted to insert a terminal block 22 that is intended for use with the terminal block socket 71c or 71d, for example, the terminal block 22 would not fit unless they rotated the terminal block 22. This would result in the wiring that is intended to be inserted into the terminal block 22 being in the way, or being difficult to insert. This will help an installer to recognize their error.

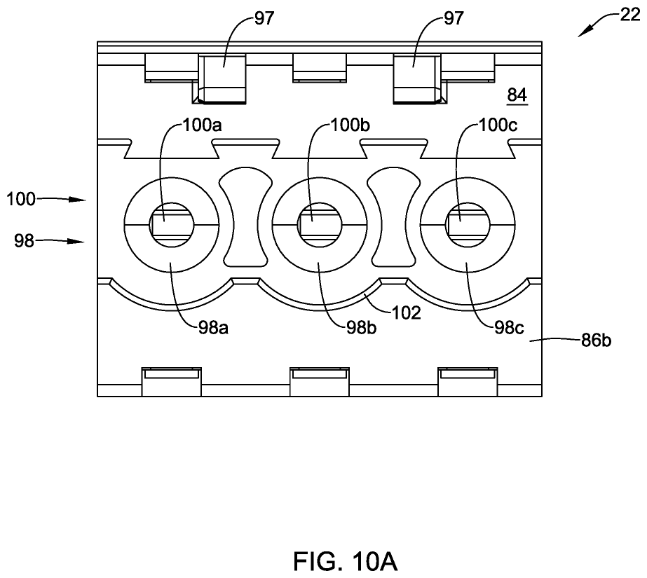

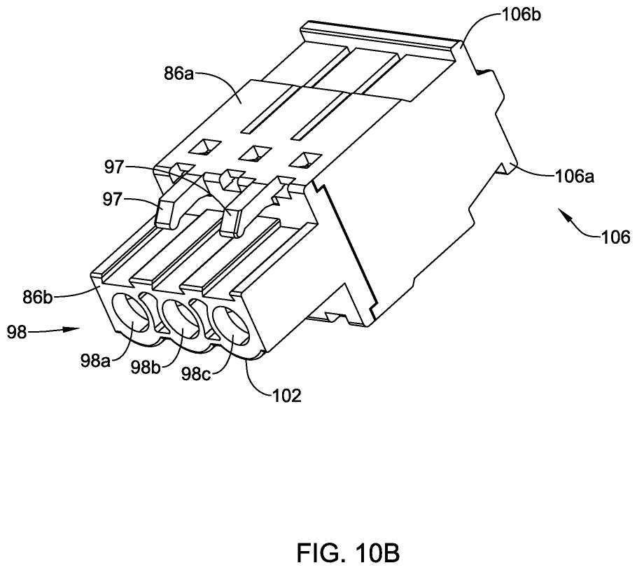

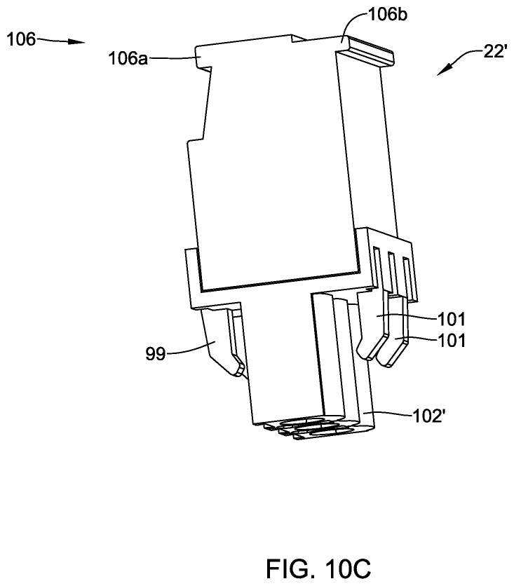

In some instances, as shown, the terminal block sockets 71a and 71b can be seen as including a raised ridge 77 that extends across the exposed front of the terminal block sockets 71a and 71b. This ridge 77 is configured to interact with clips (visible in FIGS. 10B and 10C) that help to anchor each terminal block 22 within its terminal block socket 71. The terminal block sockets 76 can be seen as also including this ridge 77. In some instances, the ridge 77 may be positioned on a side of the terminal block socket 71, 76 that is opposite to where the undulating surface 13′, 13 is located.

The circuit board 70′ includes several jumper sockets 74, individually labeled as 74a and 74b, for accepting electrical contacts within the jumper bar 24. In some cases, the circuit board 70′ may only include a single jumper socket 74 that spans the distance currently consumed by both the jumper socket 74a and the jumper socket 74b. Further details regarding the jumper sockets 74 will be discussed with respect to FIG. 15.

The illustrative circuit board 70′ includes a number of terminal block sockets 76, individually labeled as 76a, 76b, 76c and 76d, for accepting corresponding electrical contacts extending from each of a number of push-in terminal blocks 22. While a total of four terminal block sockets 76 are shown, it will be appreciated that this is merely illustrative, as the circuit board 70 may include one, two, three or more terminal block sockets 76 that are each the same size as shown, or can be different sizes. In some cases, a single terminal block socket 76 may accommodate one, two, three, four or more push-in terminal blocks 22. Each of the terminal block sockets 76 include a number of electrical pins that are electrically coupled to circuitry (not shown) on the circuit board 70′ and that are configured to electrically couple with corresponding electrical contacts within each of the push-in terminal blocks 22.

The illustrative circuit board 70′ includes several jumper sockets 78, individually labeled as 78a and 78b, for accepting electrical contacts within the jumper bar 24. In some cases, the circuit board 70′ may only include a single jumper socket 78 that spans the distance currently consumed by both the jumper socket 78a and the jumper socket 78b.

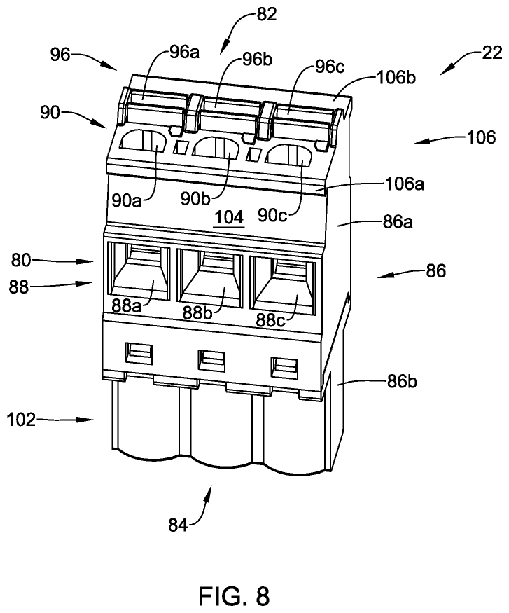

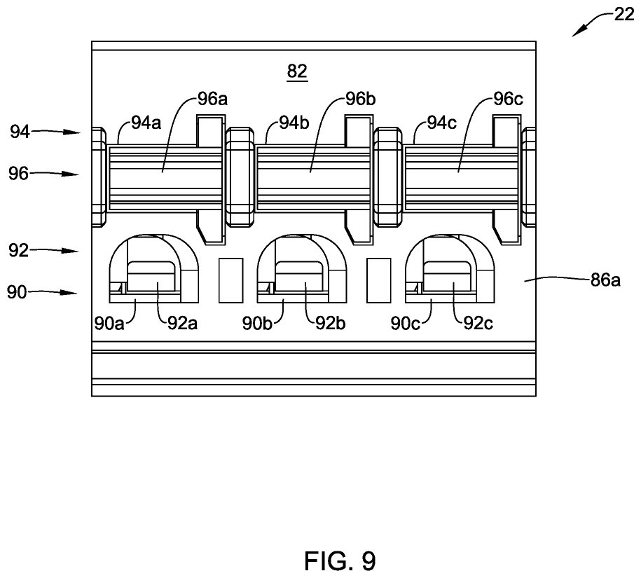

FIG. 8 is a perspective view of the push-in terminal block 22, FIG. 9 is a top view of the push-in terminal block 22, FIG. 10A is a bottom view of the push-in terminal block 22 and FIG. 10B is a rear perspective view of the push-in terminal block 22. In some cases, the push-in terminal block 22 may be considered as having a front, or first, side 80, a top, or second, side 82 and a bottom, or third, side 84. The illustrative push-in terminal block 22 includes an electrically insulative cover 86 that includes an upper cover 86a and a lower cover 86b. The electrically insulative cover 86 includes a number of wire receiving apertures 88, individually labeled as 88a, 88b and 88c, that are formed within the electrically insulative cover 86. While a total of three wire receiving apertures 88 are shown, it will be appreciated that the push-in terminal block 22 may include only one or two wire receiving apertures 88 or may include four or more wire receiving apertures 88. In some instances, each of the wire receiving apertures 88 may be configured to accommodate an electrical wire having a maximum lateral dimension of at least 2.5 millimeters, but this is not required.

The illustrative push-in terminal block 22 includes a number of test probe apertures 90, individually labeled as 90a, 90b and 90c that are formed within the top, or second, side 82. Each of the test probe apertures 90 may be considered as being configured to accommodate an electrical testing probe that may be extended into one of the test probe apertures 90. As seen in FIG. 9, an electrical test pad 92, individually labeled as 92a, 92b and 92c, is visible within each of the test probe apertures 90. As will be discussed, the electrical test pads 92 are configured to be electrically coupled with an electrical wire extending into a corresponding one of the wire receiving apertures 88. While a total of three test probe apertures 90 are shown, it will be appreciated that this is merely illustrative, as the number of test probe apertures 90 may vary, particularly if there are less than three or more than three wire receiving apertures 88.

The illustrative push-in terminal block 22 includes a number of release button apertures 94, individually labeled as 94a, 94b and 94c, disposed within the top, or second, side 82 and a number of release buttons 96, individually labeled as 96a, 96b and 96c, with one release button 96 disposed within each release button aperture 94. In some cases, actuating (e.g. depressing) a particular release button 96 makes it easier to insert an electrical wire into the corresponding wire receiving aperture 88. In some instances, actuating (e.g. depressing) a particular release button 96 makes it easier to remove an electrical wire that was already inserted into the corresponding wire receiving aperture 88. The release button 96 may be formed of an electrically insulative material such as a polymer, for example.

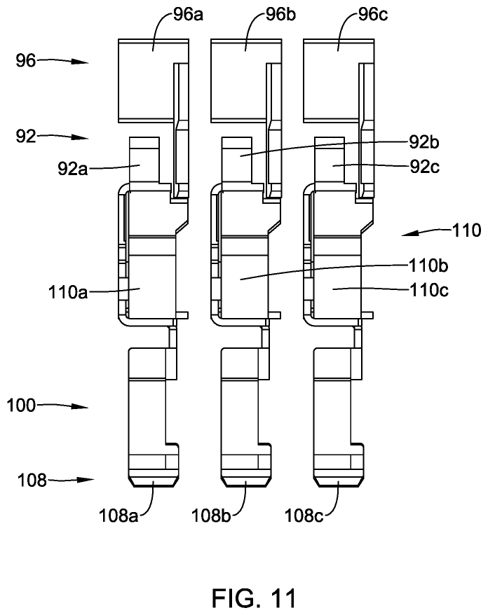

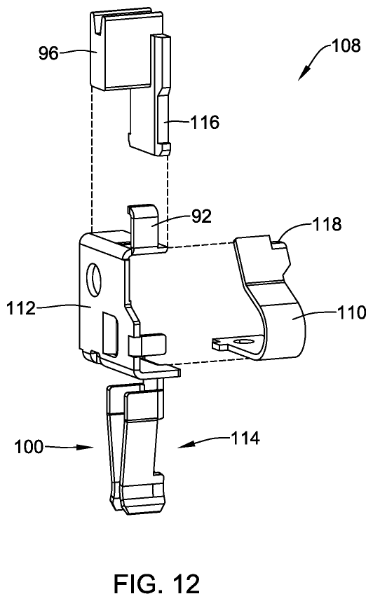

The illustrative push-in terminal block 22 includes a number of terminal pin apertures 98, individually labeled as 98a, 98b and 98c, that are disposed within the bottom, or third, side 84 of the push-in terminal block 22. In some instances, the number of terminal pin apertures 98 may vary as the number of wire receiving apertures 88 vary. Visible within each of the terminal pin apertures 98 is a corresponding terminal pin receptacle 100, individually labeled as 100a, 100b and 100c. Each terminal pin receptacle 100 may be part of a larger electrically conductive member, as will be discussed with respect to FIGS. 11 and 12. The terminal pin receptacles 100 are configured to mechanically and electrically couple to the electrical pins 75 on the circuit board 70 (see FIG. 7).

In some instances, as shown, the lower cover 86b includes several clips 97 that extend downward towards the terminal block socket 72 and 76. In some cases, the clips 97 are configured to interact with the ridge 77, forming an interference fit with the ridge 77, in order to help secure the push-in terminal block 22 to the terminal block socket 72 and 76. The clips 97 have an additional functionality. In some cases, the clips 97 may be used by an installer to secure the push-in terminal block 22 relative to the terminal block socket 72 or 76, for example, without actually fully engaging the push-in terminal block 22 within the terminal block socket 72 or 76. This allows the push-in terminal block 22 to be temporarily held while the installer connects the appropriate wiring to the wire receiving apertures 88. Once the installer has confirmed that he or she has connected each of the wires correctly, to the appropriate wire receiving aperture 88, and in some cases after the installer has appropriately configured the electronic module 10 (or 10′) to accept the wiring, the installer can lift the push-in terminal block 22 off its temporary engagement with the terminal block socket 72 or 76, and can fully engage the push-in terminal block 22 within the appropriate terminal block socket 72 or 76.

In some cases, and as shown in FIG. 10C, a push-in terminal block 22′ is configured for use with the terminal block sockets 71. The push-in terminal block 22′ is similar to the push-in terminal block 22, but includes not only a pair of clips 99, but also includes a pair of clips 101. It will be appreciated that the clips 99 will engage the ridge 77 when the push-in terminal block 22′ is fully inserted into one of the terminal block sockets 91. The clips 101 may be used to secure the push-in terminal block 22′ relative to the terminal block socket 71, for example, without actually fully engaging the push-in terminal block 22′ within the terminal block socket 71. This allows the push-in terminal block 22′ to be temporarily held while the installer connects the appropriate wiring. Once the installer has confirmed that he or she has connected each of the wires correctly, and in some cases after the installer has appropriately configured the electronic module 10 (or 10′) to accept the wiring, the installer can lift the push-in terminal block 22′ off its temporary engagement with the terminal block socket 71, and can fully engage the push-in terminal block 22′ within the appropriate terminal block socket 71′.

In some instances, and with particular reference to FIG. 9, each of the test probe apertures 90 may be considered as being orthogonal or at least substantially orthogonal to the corresponding wire receiving aperture 88. In some instances, each of the terminal pin apertures 98 may be considered as being orthogonal or at least substantially orthogonal to the corresponding wire receiving aperture 88 and may be considered as being parallel or at least substantially parallel with the corresponding test probe aperture 90. In this, substantially orthogonal means being within 10 degrees of being orthogonal and substantially parallel means being within 10 degrees of being parallel. This arrangement allows the wire receiving apertures 88 to be facing away from the electronic module 10 (see FIG. 1), thereby facilitating receiving wires that enter from the side of the electronic module 10. This allows the push-in terminal blocks 22, particularly in combination with the connecting wires, to have an overall lower profile, allowing a cover (not shown in FIG. 1) to be placed over the push-in terminal blocks 22 (and jumper bar 24), thereby protecting the push-in terminal blocks 22 and the corresponding wires (and jumper bar 24) from being inadvertently bumped and/or disconnected.

In some cases, as shown, the lower cover 86b of the push-in terminal block 22 has an undulating front surface 102 that is complementary to a shape of one of the terminal block sockets 72 shown in FIG. 7. It will be appreciated that this means that the push-in terminal block 22 can only be inserted into the terminal block socket 72 in the appropriate orientation, with the undulating front surface 102 facing forward to match the corresponding undulating surface 73 of the terminal block socket 72. The lower cover 86b may be seen as having a smaller overall profile than the upper cover 86a, which allows the lower portion of the push-in terminal block 22 to extend into a corresponding terminal block socket 72.

In some cases, the front, or first side, 80 of the push-in terminal block 22 includes a placard region 104 that is adjacent to each of the wire receiving apertures 88. The placard region 104 may be a flat surface, as shown, and may accommodate one or more labels (not shown) that identify each of the wire receiving apertures 88, or to identify each of the electrical terminals within the plug-in terminal block 22. In some cases, a top surface of the push-in terminal block 22 may include numbers or other indicia such as an integer 1, 2, 3 . . . that can be used to match corresponding numbers printed or otherwise formed on the corresponding sockets into which the push-in terminal block 22 is to be inserted. The electrical terminals will be discussed with respect to FIGS. 11 and 12.

In some instances, and with particular reference to FIG. 8, the push-in terminal block 22 may include a grasping flange 106 that is adjacent the top, or second, side 82 of the electrically insulative cover 86 that facilitates grasping and removing the push-in terminal block 22 from the corresponding terminal block socket 72. The grasping flange 106 may include a first portion 106a that extends from the top, or second, side 82 in a first direction and a second portion 106b that extends from the top, or second, side 82 in a second direction opposing the first direction.

FIG. 11 shows the push-in terminal block 22 with the cover 86 removed in order to show the internal structure. It will be appreciated that the push-in terminal block 22′ has a similar internal structure. As seen in FIG. 11, the push-in terminal block 22 includes a number of electrical terminals 108, individually labeled as 108a, 108b and 108c. It will be appreciated that the terminal pin receptacles 100 form a part of each electrical terminal 108. The test pads 92 form a part of each electrical terminal 108. Each electrical terminal 108 also includes a spring clip 110, individually labeled as 110a, 110b and 110c, which is configured to mechanically and electrically couple with an electrical wire that is inserted into a corresponding wire receiving aperture 88.

FIG. 12 is an exploded view of a single electrical terminal 108. It will be appreciated that each of the electrical terminals 108 includes the spring clip 110. The electrical terminal 108 may be considered as including a first electrical extension 112 that is electrically coupled with the spring clip 110 and which is configured to secure the spring clip 110 relative to the first electrical extension 112. The electrical terminal 108 may be considered as including a second electrical extension 114 that is configured to form a slidable mechanical and electrical connection with a corresponding electrical pin 75. The second electrical extension 114 may be considered as forming part or all of the terminal pin receptacle 100. In some cases, the first electrical extension 112, the second electrical extension 114 and the test pad 92 may be formed (e.g. stamped) from a single piece of metal, and the spring clip 110 may be separately formed and secured to the first electrical extension 112 (e.g. welded).

The release button 96, which as noted is formed of an electrically insulative material, includes an extension 116 that is configured to interact with a shoulder 118 of the spring clip 110. Pushing the release button 96 in a downward (in the illustrated orientation) direction causes the extension 116 to push downward on the shoulder 118, thereby causing the spring clip 110 to temporarily deform from its relaxed configuration (as shown), thereby reducing pressure placed on an electrical wire that is engaged between the spring clip 110 and the first electrical extension 112. This can make it easier to remove the electrical wire, for example.

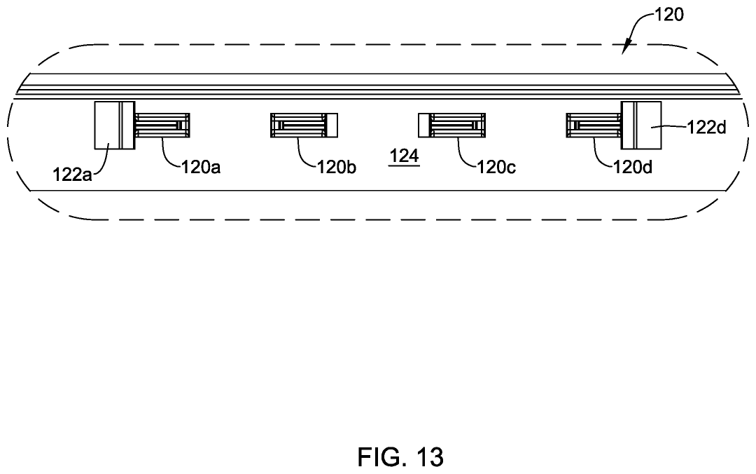

FIG. 13 is an enlarged view of a portion of FIG. 2 for receiving jumper terminals of an illustrative jumper bar as included in FIG. 1. FIG. 13 provides details as to how the jumper bar 24 interacts with the housing 12 of the electronic module 10. In the example shown, the housing 12 includes a series of apertures 120, individually labeled as 120a, 120b, 120c and 120d. While shown as a series of four distinct apertures 120, in some cases one or more of the four distinct apertures 120 may be combined into less than four distinct apertures 120. As shown, having the series of apertures 120 minimizes an amount of material removed from the housing 12, which in some cases may minimize the risk of debris or even other tools from being inserted into an interior of the housing 12 and causing damage.

As shown, the aperture 120b and the aperture 120c are similar, and are each configured to accommodate a single jumper terminal extending from the jumper bar 24. Each of the aperture 120a and the aperture 120d are also configured to accommodate a single jumper terminal extending from the jumper bar 24, but also include an enlarged portion 122a and 122d, respectively. The enlarged portion 122a and the enlarged portion 122d are configured to accommodate latch features on the jumper bar 24 in order to help hold the jumper bar 24 in place. It will be appreciated that the apertures 120 are formed within a flat surface 124 of the housing 12 of the front panel 14 of the electronic module 10, but are not centered front to back on the flat surface 124.

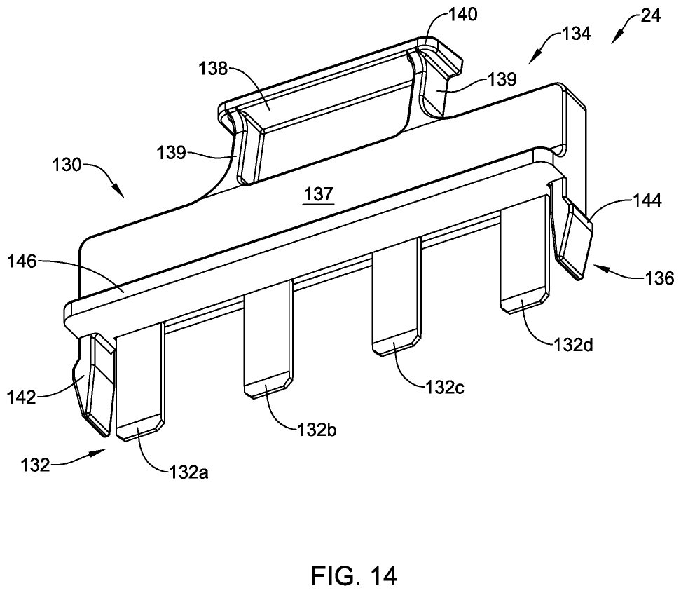

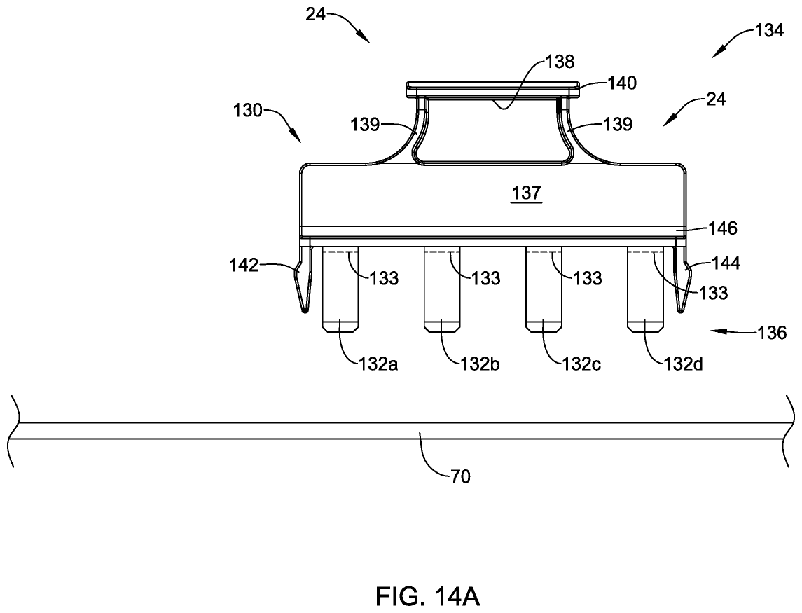

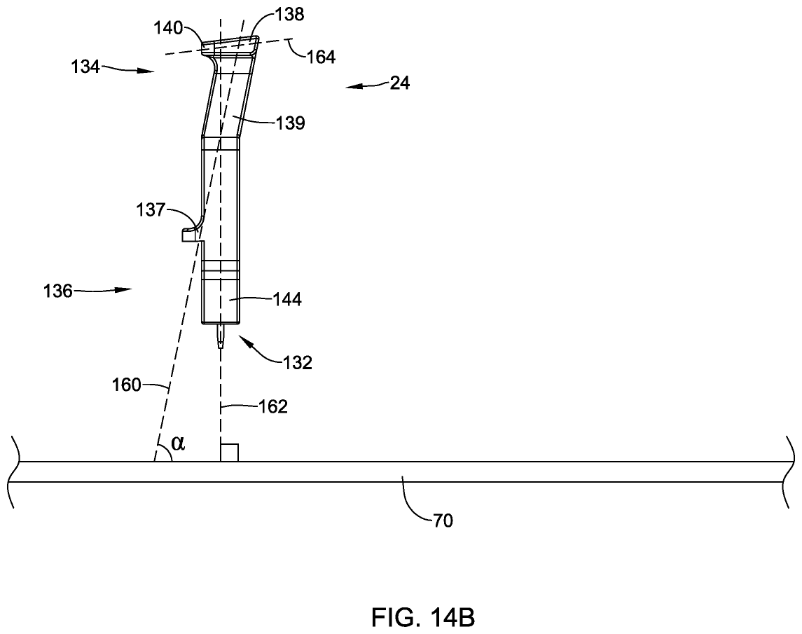

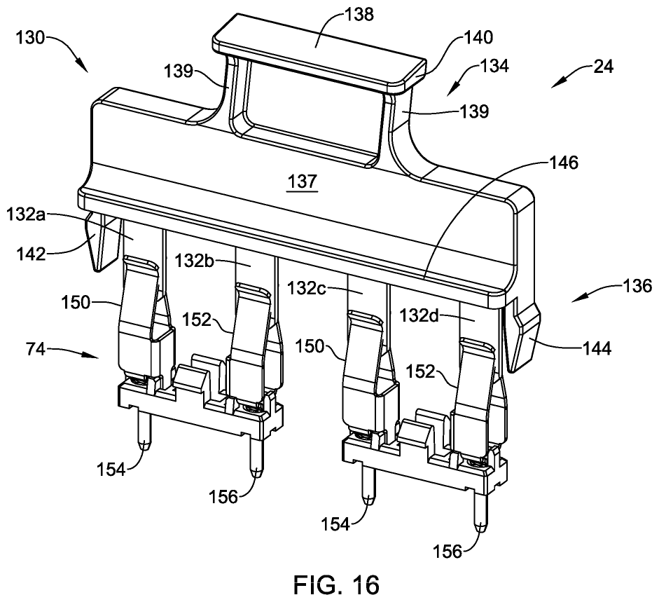

FIG. 14 is a perspective view of the illustrative jumper bar 24 shown in FIG. 1, FIG. 14A is a front view of the jumper bar 24 shown in position relative to the circuit board 70, FIG. 14B is a side view of the jumper bar 24 and circuit board 70, FIG. 15 is a perspective view showing the jumper bar 24 engaged in a pair of jumper sockets 74, and FIG. 16 is similar but shows the covers removed from the pair of jumper sockets 74. The illustrative jumper bar 24 includes a jumper body 130 and three or more spaced jumper terminals 132, individually labeled as 132a, 132b, 132c and 132d. The three or more jumper terminals 132 (four are shown) are electrically shorted together within the jumper bar 24. For example, the jumper bar 24 may include a stamped piece of metal that includes the three or more jumper terminals 132, with the stamped piece of metal electrically shorting the jumper terminals 132. In some cases, at least one of the jumper terminals 132 may be a breakaway terminal that can be broken away and removed by hand. In some instances, one or more of the jumper terminals 132 may, as shown in FIG. 14A, include a score line 133 in order to facilitate breaking of the breakaway terminal along the score line by hand without the use of a tool.

In looking briefly at FIG. 1 and FIG. 15, it will be appreciated that the jumper bar 24 includes a first part 134 that remains outside of the housing 12 of the electronic module 10 and a second part 136 of the jumper bar 24, including at least part of each of the three or more jumper terminals 132, that extend into and through the apertures 120 formed in the housing 12 of the electronic module 10. The first part 134 of the jumper bar 24 that remains outside of the housing 12 includes a graspable handle 138 having a flange 140 for pulling the jumper bar 24 from the electronic module 10 by hand, i.e., without any tools. In some instances, the graspable handle 138 is coupled to or otherwise formed with a handle support 139 that extends upwardly from a base 137. The graspable handle 138 may also be used for inserting the jumper bar 24 into the electronic module 10 by hand.

In some cases, at least part of the second part 136 of the jumper bar 24 is keyed to one or more of the jumper sockets 74 in order to prevent each of the three or more spaced jumper terminals 132 of the jumper bar 24 from engaging a non-corresponding one of the three or more terminals of the one or more jumper sockets 74. As shown, the second part 136 of the jumper bar 24 includes a first latch 142 that is keyed to fit into the aperture 120a, which includes the enlarged portion 122a and the second part 136 of the jumper bar 24 includes a second latch 144 that is keyed to fit into the aperture 120d, which includes the enlarged portion 122d. It will be appreciated that the jumper terminals 132 are disposed at or near a rear surface of the jumper bar 24 (i.e. offset from the center), and that this spacing corresponds to where the apertures 120 are formed within the flat surface 124 shown in FIG. 13.

In some cases, the first part 134 of the jumper bar 24 and the housing 12 of the electronic module 10 are keyed to prevent the jumper bar 24 from being inserted in a reverse orientation. The first part 134 of the jumper bar 24 may include a flange 146 that, in combination with the relative front-to-back spacing of the apertures 120 within the housing 12 of the electronic module 10, prevents the jumper bar 24 from being inserted in a reverse orientation.

In some cases, the jumper bar 24 may be configured to provide a minimal profile, allowing the cover 13 and/or the cover 15 to be disposed over the electronic module 10′ (or the electronic module 10). As can be seen for example in FIG. 14B, the handle support 139 traverses along a plane 160 that is non-orthogonal to the circuit board 70, and in fact forms an acute angle α (alpha) with the circuit board 70. In contrast, the second part 136 of the jumper bar 24, traverses along a plane 162 that is orthogonal to the circuit board 70. The handle 138 can be seen as extending along a plane 164 that is non-parallel with the circuit board 70 and that is not orthogonal to either the plane 160 or the plane 162. It will be appreciated that in some cases, the plane 164 is parallel to the cover 13 and/or the cover 15, depending on where the jumper bar 24 has been installed.

As seen in FIG. 16, which shows the jumper sockets 74 with their external covers removed, each of the jumper sockets 74 includes a first terminal 150 and a second terminal 152. The first terminal 150 and the second terminal 152 are each configured to mechanically and electrically couple with the corresponding jumper terminal 132. The first terminal 150 and the second terminal 152 are each configured to allow a corresponding jumper terminal 132 to slide into the first terminal 150 and the second terminal 152, respectively, and to hold the corresponding jumper terminals 132 against incidental movement. However, if a user grasps the handle 138 and pulls, the first terminal 150 and the second terminal 152 are each configured to release the corresponding jumper terminals 132 held within the first terminal 150 and the second terminal 152.

Each of the jumper sockets 74 include a pin 154 and a pin 156 that may be used to mechanically and electrically connect the jumper socket 74 to the circuit board 70. The pin 154 may be electrically coupled with the first terminal 150, for example, and the pin 156 may be electrically coupled with the second terminal 152. Accordingly, the pins 154 and 156 may be used to provide an electrical connection between the first terminal 150 and the circuit board 70, and thus provide an electrical connection between two contact points (not shown) on the circuit board 70, and to thus electrically short together those two contact points.

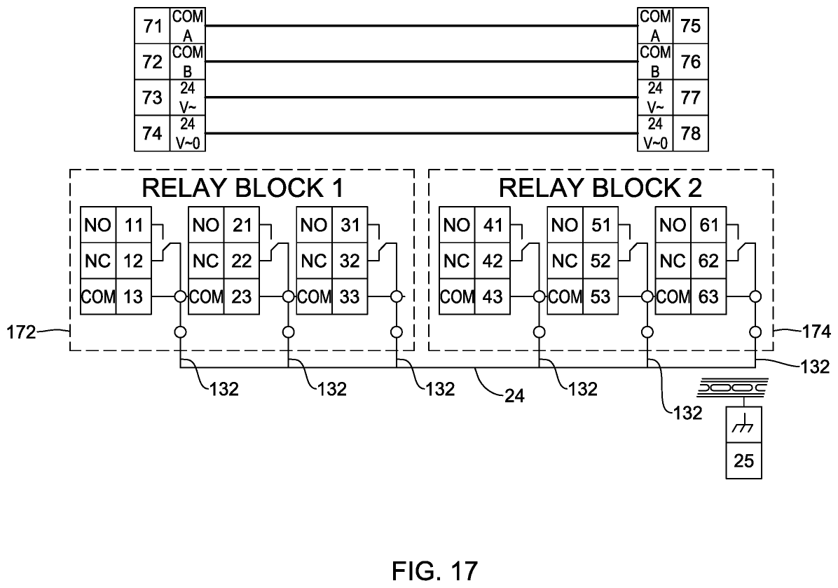

FIG. 17 is a schematic diagram 170 showing how the jumper bar 24 may be used to electrically couple the common terminal of one of two or more different relays that are controlled by the electronic module 10 or 10′. The schematic diagram 170 includes a first relay block 172 and a second relay block 174. The first relay block 172 includes three relays having a common terminal labeled COM13, a common terminal labeled COM23 and a common terminal labeled COM33. The second relay block 174 includes three relays having a common terminal labeled COM 43, a common terminal labeled COM53 and a common terminal labeled COM63. The jumper bar 24, which as shown here includes more than four jumper terminals 132, and in fact includes a total of six jumper terminals 132.

Those skilled in the art will recognize that the present disclosure may be manifested in a variety of forms other than the specific embodiments described and contemplated herein. Accordingly, departure in form and detail may be made without departing from the scope and spirit of the present disclosure as described in the appended claims.

What is claimed is:

1. An apparatus comprising:
an electronic module including:
one or more circuit boards including one or more jumper sockets, the one or more jumper sockets defining three or more terminals;
a housing configured to house the one or more circuit boards, the housing including one or more apertures for accessing the three or more terminals defined by the one or more jumper sockets from external to the housing;
a jumper bar comprising:
a jumper body;
three or more spaced jumper terminals secured to and extending away the jumper body, the three or more jumper terminals electrically shorted together;
the jumper bar positioned relative to the electronic module such that:
a first part of the jumper bar remains outside of the housing of the electronic module;
a second part of the jumper bar, which includes at least part of each of the three or more spaced jumper terminals of the jumper bar, extends into and through one or more of the apertures in the housing of the electronic module;
each of the three or more spaced jumper terminals of the jumper bar electrically engage a corresponding one of the three or more terminals defined by the one or more jumper sockets of the one or more circuit boards of the electronic module; and
the first part of the jumper bar that remains outside of the housing of the electronic module includes a graspable handle with a flange for pulling the jumper bar from the electronic module by hand.

2. The apparatus of claim 1, wherein at least part of the second part of the jumper bar is keyed to one or more of the jumper sockets to prevent each of the three or more spaced jumper terminals of the jumper bar from engaging a non-corresponding one of the three or more terminals of the one or more jumper sockets of the one or more circuit boards of the electronic module.

3. The apparatus of claim 1, wherein the first part of the jumper bar and the housing of the electronic module are keyed to prevent the jumper bar from being inserted in a reverse orientation.

4. The apparatus of claim 1, wherein the electronic module further comprises one or more removable terminal blocks that extend external to the housing of the electronic module, the one or more removable terminal blocks spaced from the first part of the jumper bar to allow a hand to grasp the graspable handle of the first part of the jumper bar.

5. The apparatus of claim 4, wherein the first part of the jumper bar comprises:
an elongated base that is positioned adjacent the housing of the electronic module, wherein the three or more spaced jumper terminals are spaced along a length direction of the elongated base, and are offset toward one side of the elongated base in a width direction of the elongated base;
a handle support that extends from the elongated base and away from the three or more spaced jumper terminals; and
the graspable handle supported by the handle support.

6. The apparatus of claim 5, wherein the handle support traverses along a plane that is non-orthogonal to the one or more circuit boards.

7. The apparatus of claim 6, wherein the housing of the electronic module has an outer surface that extends along a plane that is non-orthogonal to the one or more circuit boards to match the handle support.

8. The apparatus of claim 1, wherein at least one of the three or more spaced jumper terminals is a breakaway terminal that can be broken away and removed by hand.

9. The apparatus of claim 8, wherein the breakaway terminal includes a score line to facilitate breaking of the breakaway terminal along the score line by hand.

10. The apparatus of claim 1, wherein at least two of the three or more terminals defined by the jumper sockets correspond to a common terminal of a corresponding one of two or more relays that are controlled by the electronic module.

11. A jumper bar comprising:
three or more spaced jumper terminals electrically shorted together; and
a jumper body including an elongated base, wherein each of the three or more spaced jumper terminals are secured to the elongated base at spaced locations along a length direction of the elongated base and extend away from the elongated base in a first direction, and wherein the spaced locations are offset toward one side of the elongated base in a width direction.

12. The jumper bar of claim 11, wherein the jumper body further comprises:
a handle support that extends from the elongated base away from the first direction; and
a graspable handle supported by the handle support.

13. The jumper bar of claim 12, wherein the graspable handle includes a flange that extends out from the handle support in a lateral direction more than the flange extends out from the handle support in an opposite direction that is opposite to the lateral direction.

14. The jumper bar of claim 12, wherein the handle support traverses along a plane that is non-parallel to the three or more spaced jumper terminals.

15. The jumper bar of claim 11, wherein the jumper body further includes one or more non-conductive interference features spaced from but extending alongside one or more of the three or more spaced jumper terminals.

16. The jumper bar of claim 11, wherein at least one of the three or more spaced jumper terminals is a breakaway terminal that can be broken away and removed by hand.

17. A jumper bar comprising:
three or more spaced jumper terminals electrically shorted together;
a jumper body including an elongated base, wherein each of the three or more spaced jumper terminals are secured to the elongated base at spaced locations along a length direction of the elongated base and extend away from the elongated base in a first direction;
a handle support that extends from the elongated base away from the first direction; and
a graspable handle supported by the handle support, wherein the graspable handle includes a flange that extends out from the handle support in a lateral direction.

18. The jumper bar of claim 17, wherein at least one of the three or more spaced jumper terminals is a breakaway terminal that can be broken away and removed by hand.

19. The jumper bar of claim 17, wherein the spaced locations are offset toward one side in a width direction of the elongated base.

20. The jumper bar of claim 17, wherein the flange extends out from the handle support in the lateral direction more than the flange extends out from the handle support in an opposite direction that is opposite to the lateral direction.
